(19) United States
(12) Patent Application Publication
(10) Pub. No.: US 2020/0288570 A1
(43) Pub. Date: Sep. 10, 2020

(54) Circuit Board with Improved Thermal, Moisture Resistance, and Electrical Properties

(71) Applicant: OSI Electronics, Inc., Hawthorne, CA (US)

(72) Inventors: Robert Jung, Fremont, CA (US); Konstantine Karavakis, Pleasanton, CA (US)

(21) Appl. No.: 16/359,840

(22) Filed: Mar. 20, 2019

Related U.S. Application Data
(60) Provisional application No. 62/813,513, filed on Mar. 4, 2019.

(51) Int. Cl. H05K 1/03; H05K 1/11; H05K 3/28

(52) U.S. Cl. CPC H05K 1/0326; H05K 1/0353; H05K 1/112; H05K 1/118; H05K 2203/068; H05K 2201/0141; H05K 2201/0145; H05K 2201/0195; H05K 2201/0191; H05K 3/285

(57) ABSTRACT

A circuit board with improved reliability and ability to withstand sonication, autoclave sterilization, moisture exposure and high pH solution exposure. The circuit board has a substrate made of a liquid crystal polymer, one or more vias extending through the substrate, conductive traces positioned on surfaces of the substrate, and cover layers made of liquid crystal polymer material positioned over surfaces of the substrate.

### CROSS-REFERENCE

The present application relies on U.S. Provisional Patent Application No. 62/813,513, entitled “Flexible Circuit Board and Methods of Manufacturing Thereof” and filed on Mar. 4, 2019, for priority, which is incorporated herein by reference in its entirety.

### FIELD

The present specification is related generally to the field of circuit boards. More specifically, the present specification is related to manufacturing a circuit board that uses liquid crystal polymer films as substrate as well as cover layers.

### BACKGROUND

Circuit boards, including flexible circuit boards (FCBs), are electronic circuits that are frequently used in a variety of modern electronic devices. A FCB comprises circuit traces and electronic components deposited onto a flexible substrate or laminate. FCBs typically comprise silicon substrates and etched thin metal foils and are so named because of their ability to bend, twist or flex. They have the advantage of being thin, thus saving space, and of being easily moldable to the shape of the electronic device. They are often used to form a connection between two separate circuits.

With continued demand for miniaturization and high-density circuit designs, circuit boards and FCBs have become more complex in design and manufacturing process. Also, certain applications require the circuit boards and FCBs to undergo extreme reliability tests such as, but not limited to, sonication, autoclave sterilization and high pH solution exposure. In addition, the circuit boards and FCBs are required to be moisture resistant and demonstrate high weatherability. Conventional circuit board and FCB materials, such as polyimides substrates and polyimide or flexible liquid photoimageable (LPI) solder masks, often fail because they do not have the desired combination of thermal properties, moisture resistivity, and electrical properties.

Thus, there is a need for a circuit board structure and a process of manufacturing circuit boards that overcome the shortcomings of conventional materials such as, for example, polyimides.

### SUMMARY

The following embodiments and aspects thereof are described and illustrated in conjunction with systems, tools and methods, which are meant to be exemplary and illustrative, and not limiting in scope. The present application discloses numerous embodiments.

The present specification discloses a circuit board comprising: a substrate comprising a first liquid crystal polymer and two opposing sides, wherein the first of the two opposing sides defines a first surface layer and wherein the second of the two opposing sides defines a second surface layer; one or more vias extending through the substrate and two opposing sides, wherein each of the one or more vias comprises conductive material; a plurality of conductive traces positioned on at least one of the two opposing sides; a first adhesive positioned on the first surface layer; a second adhesive positioned on the second surface layer; a first cover layer positioned over the first adhesive on the first surface layer, wherein the first cover layer comprises a second liquid crystal polymer; and a second cover layer positioned over the second adhesive on the second surface layer, wherein the second cover layer comprises a third liquid crystal polymer.

Optionally, the first liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

Optionally, second liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

Optionally, the third liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

Optionally, the first liquid crystal polymer, second liquid crystal polymer, and third liquid crystal polymer are a same liquid crystal polymer.

Optionally, the first liquid crystal polymer has a thickness in a range of 25 to 75 microns.

Optionally, each of the first liquid crystal polymer or second liquid crystal polymer has a thickness in a range of 25 to 75 microns.

Optionally, the adhesive covers all of the first surface layer. Optionally, the adhesive covers all of the second surface layer.

Optionally, the first liquid crystal polymer has a thickness that is less than a thickness of the second liquid crystal polymer and less than a thickness of the third liquid crystal polymer and the thickness of the second liquid crystal polymer is equal to the thickness of the third liquid crystal polymer.

Optionally, the first liquid crystal polymer has a thickness that is more than a thickness of the second liquid crystal polymer and more than a thickness of the third liquid crystal polymer and the thickness of the second liquid crystal polymer is equal to the thickness of the third liquid crystal polymer.

Optionally, the first liquid crystal polymer has a thickness that is equal to a thickness of the second liquid crystal polymer and equal to a thickness of the third liquid crystal polymer and the thickness of the second liquid crystal polymer is equal to the thickness of the third liquid crystal polymer.

Optionally, in each of the one or more vias, the conductive material is configured to interconnect one of the plurality of conductive traces on the first surface layer with another one of the plurality of conductive traces on the second surface layer.

The present specification also discloses a circuit board comprising: a liquid crystal polymer substrate defined by a thickness of 25 to 75 microns and including two opposing sides, wherein the first of the two opposing sides defines a first surface layer and wherein the second of the two opposing sides defines a second surface layer; one or more vias extending through the substrate and two opposing sides, wherein each of the one or more vias comprises at least one of conductive material or material plated to one or more walls of each of the one or more vias; a plurality of conductive traces positioned on at least one of the two opposing sides, wherein each of the one or more vias is configured to interconnect one of the plurality of conductive traces on the first surface layer with another one of the plurality of conductive traces on the second surface layer; a first adhesive positioned on the first surface layer, wherein the adhesive covers all of the first surface layer; a second adhesive positioned on the second surface layer, wherein the adhesive covers all of the second surface layer; a first cover layer positioned over the first adhesive on the first surface layer, wherein the first cover layer comprises a second liquid crystal polymer; and a second cover layer positioned over the second adhesive on the second surface layer, wherein the second cover layer comprises a third liquid crystal polymer.

Optionally, each of the first liquid crystal polymer, the second liquid crystal polymer, and the third liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

Optionally, the first liquid crystal polymer, second liquid crystal polymer, and third liquid crystal polymer are a same liquid crystal polymer.

Optionally, the first liquid crystal polymer has a thickness that is less than a thickness of the second liquid crystal polymer and less than a thickness of the third liquid crystal polymer and the thickness of the second liquid crystal polymer is equal to the thickness of the third liquid crystal polymer.

Optionally, the first liquid crystal polymer has a thickness that is less than a thickness of the second liquid crystal polymer and less than a thickness of the third liquid crystal polymer.

Optionally, the first liquid crystal polymer has a thickness that is equal to a thickness of the second liquid crystal polymer and equal to a thickness of the third liquid crystal polymer.

Optionally, the first liquid crystal polymer has a thickness that is more than a thickness of the second liquid crystal polymer and more than a thickness of the third liquid crystal polymer and the thickness of the second liquid crystal polymer is equal to the thickness of the third liquid crystal polymer.

Optionally, a wide window is laser cut in circuit areas that need to be laser routed for singulation, and carbon and metal residue deposited on walls of said circuit areas due to singulation is cleaned through plasma cleaning.

The present specification also discloses a method of manufacturing a circuit board, the method comprising: obtaining a base film comprising a first substrate layer of a first liquid crystal polymer having first and second opposing sides, wherein a first conducting layer is positioned on the first side and a second conducting layer is positioned on the second side; forming at least one via, wherein said at least one via extends through the first substrate layer and the first and second opposing sides, and wherein said at least one via comprises conductive material; coating a conductive bridge over the first substrate layer within the at least one via; electroplating walls of and filling the at least one via with conductive material; forming a plurality of circuit areas on at least one of the first and second conducting layers; obtaining first and second cover layers, wherein the first cover layer comprises a second substrate layer of second liquid crystal polymer and the second cover layer comprises a third substrate layer of third liquid crystal polymer; applying adhesive to a side of each of the first and second cover layers; forming at least one via in the first and second cover layers applied with adhesive; and tacking in place the first and second cover layers with adhesive over the first and second conducting layers, respectively.

Optionally, the method further comprises: cutting a wide window in said circuit areas that need to be laser routed for singulation; and cleaning carbon and metal residue deposited on walls of said circuit areas.

The aforementioned and other embodiments of the present shall be described in greater depth in the drawings and detailed description provided below.

### BRIEF DESCRIPTION OF THE DRAWINGS

These and other features and advantages of the present specification will be further appreciated, as they become better understood by reference to the following detailed description when considered in connection with the accompanying drawings:

FIG. 1 illustrates a cross-sectional view of a flexible circuit board (FCB), in accordance with some embodiments of the present specification;

FIG. 2 illustrates a cross-sectional view of a flexible conductor-clad base film, in accordance with some embodiments of the present specification;

FIG. 3 illustrates a cross-sectional view of the conductor-clad base film with at least one formed via, in accordance with some embodiments of the present specification;

FIG. 4 illustrates a cross-sectional view of the conductor-clad base film with a conductive bridge in the at least one via, in accordance with some embodiments of the present specification;

FIG. 5 illustrates a cross-sectional view of the conductor-clad base film of FIG. 4 with a dry film photoresist applied on the conducting layers of the base film, in accordance with some embodiments of the present specification;

FIG. 6 illustrates a cross-sectional view of the conductor-clad base film of FIG. 5 with the at least one via filled and/or lined with electrically conductive material, in accordance with some embodiments of the present specification;

FIG. 7A illustrates a cross-sectional view of the conductor-clad base film of FIG. 6 coated with a light sensitive dry film photoresist for photolithography, in accordance with some embodiments of the present specification;

FIG. 7B illustrates a cross-sectional view of a circuitized or patterned FCB, in accordance with some embodiments of the present specification;

FIG. 7C illustrates a plan view of the circuitized or patterned FCB, in accordance with some embodiments of the present specification;

FIG. 8A illustrates a cross-sectional view of another flexible conductor-clad base film, in accordance with some embodiments of the present specification;

FIG. 8B illustrates a cross-sectional view of first and second cover layers, in accordance with some embodiments of the present specification;

FIG. 9 illustrates a cross-sectional view of circuitized or patterned FCB of FIG. 7B encapsulated on both sides, respectively, by first and second cover layers, in accordance with some embodiments of the present specification;

FIG. 10 shows a final FCB product for shipping to an end-user for further processing; and,

FIG. 11 is a flowchart of a plurality of exemplary steps of a method of manufacturing of the FCB of the present specification.

### DETAILED DESCRIPTION

The present specification discloses a flexible circuit board (FCB), semi-rigid circuit board, or rigid circuit board fabricated using liquid crystal polymer (LCP) films as substrate material as well as for cover layers of the FCB, semi-rigid, or rigid circuit board.

A “via” (vertical interconnect access) is an electrical connection between layers in a flexible electronic circuit that passes through the plane of one or more layers.

“Automated optical inspection” (AOI) is an automated visual inspection of FCB (Flexible Circuit Board) manufacture where a camera autonomously scans the FCB under test for both catastrophic failure (example, missing features) and quality defects (example, fillet size or shape or feature skew).

A “flexible circuit board” is a circuit board that may be easily manipulated about a flat plane to conform to a desired shape through the application of minimal force.

A “semi-rigid circuit board” is a circuit board that may be manipulated about a flat plane to conform to a desired shape through the application of a force greater than the force required to manipulate a flexible circuit board.

A “rigid circuit board” is a circuit board with a fixed shape that cannot be manipulated about a flat plane.

The present specification is directed towards multiple embodiments. The following disclosure is provided in order to enable a person having ordinary skill in the art to practice the invention. Language used in this specification should not be interpreted as a general disavowal of any one specific embodiment or used to limit the claims beyond the meaning of the terms used therein. The general principles defined herein may be applied to other embodiments and applications without departing from the spirit and scope of the invention. Also, the terminology and phraseology used is for the purpose of describing exemplary embodiments and should not be considered limiting. Thus, the present invention is to be accorded the widest scope encompassing numerous alternatives, modifications and equivalents consistent with the principles and features disclosed. For purpose of clarity, details relating to technical material that is known in the technical fields related to the invention have not been described in detail so as not to unnecessarily obscure the present invention.

In the description and claims of the application, each of the words “comprise” “include” and “have”, and forms thereof, are not necessarily limited to members in a list with which the words may be associated. It should be noted herein that any feature or component described in association with a specific embodiment may be used and implemented with any other embodiment unless clearly indicated otherwise.

As used herein, the indefinite articles “a” and “an” mean “at least one” or “one or more” unless the context clearly dictates otherwise.

### Circuit Board Overview

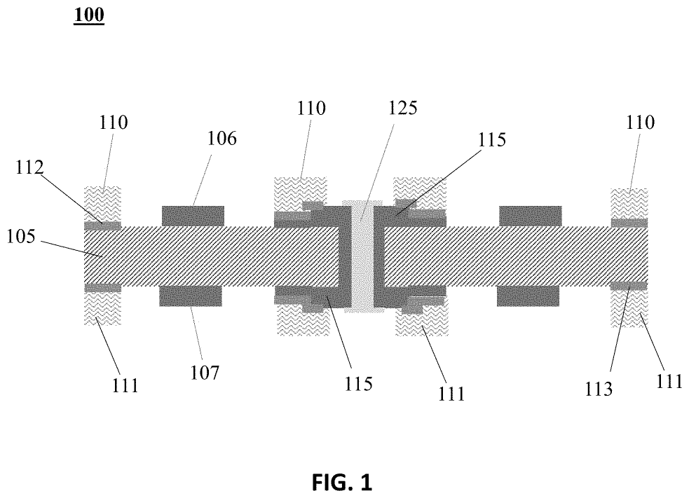

The circuit boards disclosed in the embodiments of the present specification comprise flexible, semi-rigid, or rigid circuit boards and the methods of manufacture disclosed in the embodiments of the present specification can be used to manufacture flexible, semi-rigid, or rigid circuit boards. In some embodiments, flexibility of the circuit board is dependent on the number of layers comprising the circuit board. In some embodiments, for example, for a multilayer circuit board having more than two layers, the final board thickness will increase the rigidity of the board making the board semi-rigid or rigid. While the following figures are described with reference to a flexible circuit board (FCB), they also apply to semi-rigid and rigid circuit boards. FIG. 1 illustrates a cross-sectional view of a flexible circuit board 100, in accordance with some embodiments of the present specification. In embodiments, the FCB 100 comprises a flexible conductor-clad layer or film comprising a dielectric insulating substrate 105, a first conducting layer 106 positioned on a first side of the substrate 105 and a second conducting layer 107 positioned on a second, opposing side of the substrate 105. In various embodiments, the first and second conducting layers 106, 107 comprise a plurality of surface-mounted electronic components that are electrically connected to each other through a plurality of conductive pads or lands, conductive traces, and conductive vias such as via 125. A conductive via is a hole lined (that is, the via walls are lined or plated) and/or filled with a conductor metal such as, for example, copper. In some embodiments, the conductive via 125 interconnects the first and second conducting layers 106, 107 of the FCB 100. Vias may be through-hole, blind and/or buried vias depending upon the design, interconnection needs and the number of layers (in case of multi-layered circuit boards) of a FCB. Also shown are annular rings 115 representing areas on the pad that surrounds the via 125.

The FCB 100 further comprises first and second cover layers 110, 111 that are applied and tacked in place over the first and second sides of the substrate 105, respectively, in order to protect the plurality of conductive pads and traces formed in the first and second conducting layers 106, 107. In some embodiments, dielectric adhesive layers or films 112, 113 are positioned under the first and second cover layers 110, 111, respectively, to help the layers 110, 111 adhere or bond to the plurality of conductive pads and traces on the first and second sides of the substrate 105.

In accordance with aspects of the present specification, the substrate 105 and the cover layers 110, 111 of the FCB 100 are comprised of liquid crystal polymer (LCP) material. This is in contrast to conventional circuit boards that use polyimide films as substrate material and polyimide cover layers or flexible liquid photoimageable (LPI) solder masks.

LCPs are compounds made of partially crystalline aromatic polyesters. Non-limiting examples of LCPs which may be used as polymer films in the fabrication of the substrate 105 and cover layers 110, 111 include polyesters comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, and a polyester comprising monomer units derived from 4-hydroxybenzoic acid, terephthalic acid and 4,4′-biphenol.

More broadly, LCPs which may be used as polymer films in the fabrication of the substrate 105 and cover layers 110, 111 include polyesters comprising at least one of the following: one or more aromatic dicarboxylic acids and alicyclic dicarboxylic acids; one or more aromatic diols, alicyclic diols and aliphatic diols; one or more aromatic hydroxy-carboxylic acids; one or more aromatic thiocarboxylic acids; one or more aromatic dithiols and aromatic dithiophenols; and/or one or more aromatic hydroxy hydroxylamines and aromatic diamines.

Additional non-limiting examples comprise thermotropic polymer films of commercially available LCP identified by the brand-names VECTRA (naphthaline based, available from Hoechst Celanese Corporation), and XYDAR® (available from Amoco Performance Products and comprising units derived from 4-hydroxybenzoic acid, terephthalic acid and 4,4′-biphenol), as well as other mesogenic group-containing LCPs. Examples of VECTRA® brand of LCPs include VECTRA® A polyester comprising 73 mole % of monomer units derived from 4-hydroxybenzoic acid (HBA) and 27 mole % of monomer units derived from 2,6-hydroxynaphthoic acid (HNA), VECTRA® E polyester comprising 60 mole % of monomer units derived from HBA, 4 mole % of monomer units derived from HNA, 18 mole % of monomer units derived from terephthalic acid (TA), and 18 mole % of monomer units derived from p,p′-biphenol, VECTRA® C polyester comprising 80 mole % of monomer units derived from HBA and 20 mole % of monomer units derived from HNA and VECTRA® B polyester comprising 60 mole % of monomer units derived from HNA, 20 mole % of monomer units derived from TA, and 20 mole % of monomer units derived from acetaminophen. Still additional example comprises commercially available LCP from Panasonic® identified by the brand-name FELIOS® LCP including R-F705S and R-F705T series, for example.

### LCP Properties

LCPs possess properties that make them particularly suitable for use as the substrate 105 and the first and second cover layers 110, 111 of the FCB 100, compared to conventionally available flex circuit substrates, particularly polyimide films such as KAPTON™ and APICAL™. LCPs are thermoplastic polymers consisting of rigid and flex monomers that are biocompatible, chemically inert, and thermally and mechanically stable with good weatherability. These polymers have a low-moisture uptake such that there is no or very slight hygroscopic expansion and thus no change in electrical properties or dimensions. Compared to polyimides that have a moisture absorption of 2.8%, LCPs have a very low moisture absorption of less than 0.04%. LCPs have a lower dielectric constant of less than 3.0, e.g. around 2.9, compared to polyimides, e.g. around 3.3. Also, the tensile strength of LCPs are in a range of 270 to 500 MPa while that of polyimides are around 128 MPa. Prior art circuit boards that use polyimide films as substrate material and polyimide cover layers or flexible liquid photoimageable (LPI) solder mask are also susceptible to high pH solution exposure.

Additionally, LCPs have a relatively high Z-axis coefficient of thermal expansion. They resist stress cracking in the presence of most chemicals at elevated temperatures, including aromatic or halogenated hydrocarbons, strong acids, bases, ketones, and other aggressive industrial substances. LCP are characterized by low relative dielectric constants, low dissipation factors and excellent hydrolytic stability in boiling water. Following are a plurality of generic properties or characteristics of solid LCP:

Solid LCP properties

| Specific Gravity | 1.38 to 1.95 | |
|---|---|---|
| Elasticity modulus (E) | 8530 to 17200 | MPa |
| Tensile strength (σₜ) | 52.8 to 185 | MPa |
| Tensile Elongation (%) | 0.26 to 6.2 | |
| Notched Izod Impact | 21.0 to 82.5 | kJ/m² |

These unique properties of LCP make it suitable for applications (such as, for example, medical applications) where the FCB 100 must undergo extreme reliability tests such as, but not limited to, sonication, autoclave sterilization and high pH solution exposure. In some embodiments, materials other than LCP, but having the similar properties as LCP, as described throughout this specification, are used for the circuit board.

### Manufacturing Steps

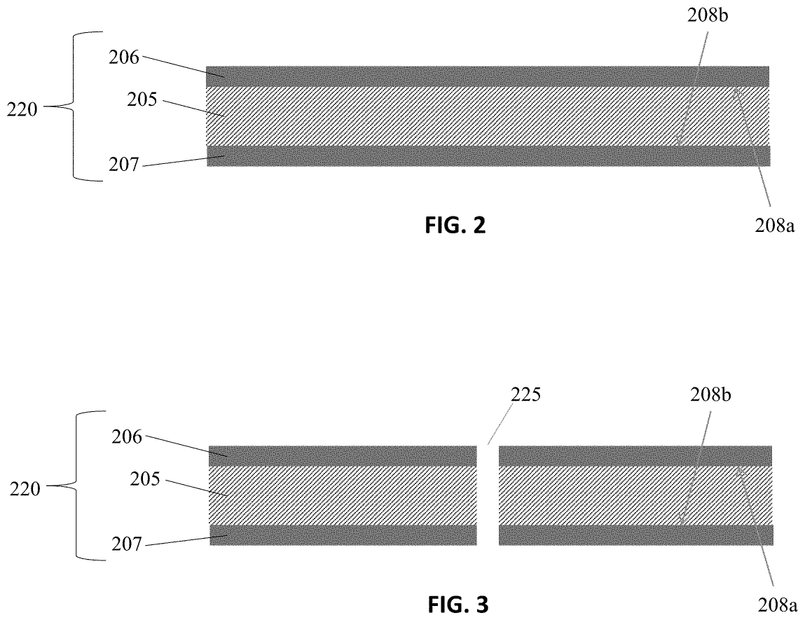

FIG. 2 through FIG. 9 depict cross-sectional views of exemplary manufacturing steps of a FCB of the present specification.

FIG. 2 illustrates a cross-sectional view of a flexible conductor-clad base film 220, in accordance with embodiments of the present specification. Referring to FIG. 2, the starting material of the FCB (such as the FCB 100 of FIG. 1) is the flexible conductor-clad base film 220 comprising a LCP substrate layer 205 having a first side 208a and a second side 208b. The LCP substrate layer 205 has a first conducting layer 206 laminated to the first side 208a and a second conducting layer 207 laminated to the second side 208b of the LCP substrate layer 205 thereby resulting in the flexible base film 220.

In some embodiments, the first and second conducting layers 206, 207 comprise metal foils such as, for example, copper foil, aluminum foil, copper-beryllium alloy, or a metal filled conductive polymer.

In some embodiments, the flexible base film 220 is a substantially rectangular strip of a predetermined length to support fabrication, thereon, of at least one FCB. In some embodiments, the flexible base film 220 is received in the form of a roll or sheet and cut to size in order to fabricate at least one FCB thereon. In some embodiments, the flexible base film 220 has the first conducting layer 206 of thickness 18 micron, the LCP substrate layer 205 of thickness 25 micron and the second conducting layer 207 of thickness 18 micron. In various embodiments, a thickness of the LCP substrate layer 205 may range from 25 micron to 75 micron.

In one embodiment, the starting material of the FCB is a Panasonic R-F705S series of copper-clad LCP wherein the first copper layer 206 is of thickness 0.7 mils, the LCP substrate layer 205 is of thickness 1 mil and the second copper layer 207 is of thickness 0.7 mils wherein 1 mil is 1/1000 inch.

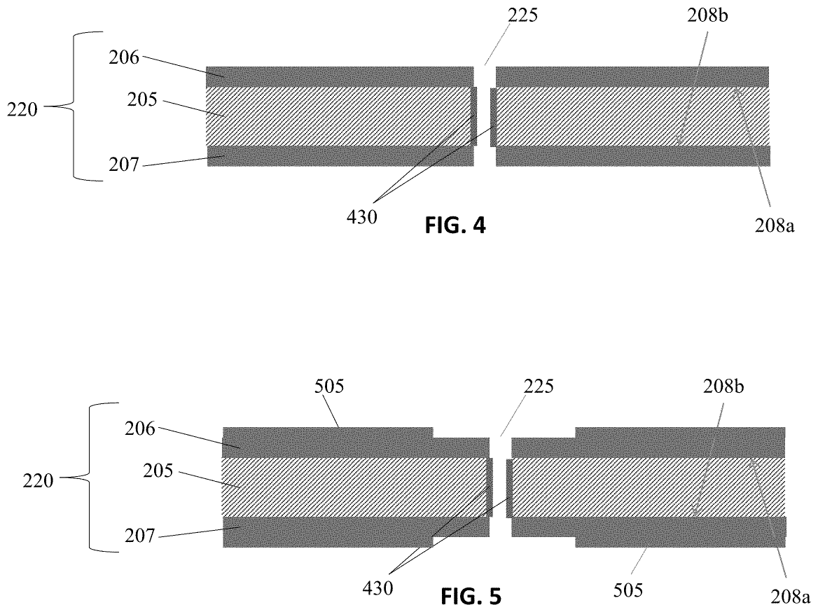

FIG. 3 illustrates a cross-sectional view of the base film 220 with at least one formed opening, hole or via, in accordance with some embodiments. Referring now to FIG. 3, at least one opening, hole or via 225 is formed in the base film 220 by an ultraviolet (UV) based laser, a carbon dioxide based laser, or by any other known methods, such as, but not limited to, mechanical drilling, depth-controlled laser drilling or punching. In an embodiment, for exemplary illustrative purposes, the via 225 is shown as a single through-hole. However, in alternate embodiments a plurality of through-hole, blind and/or buried vias may be formed depending upon the desired design and surface mount of the FCB. In various embodiments, one or more openings or holes, formed in the FCB, comprise at least one of the following types: a) tooling holes formed outside of formed circuit areas for positioning the base film 220 during subsequent processing. The sequence of FCB fabrication steps requires close alignment from one process to the next, and the tooling holes are used with locating pins at each step to achieve accurate registration/alignment; b) insertion holes for inserting electronic component leads therein; and c) via holes, such as the at least one via 225, that are later electroplated and used as conducting paths between the conducting layers of the FCB.

Once the at least one opening, hole or via 225 is formed in the base film 220 the via is cleaned or de-smeared using plasma cleaning to remove unwanted residue or by-products left behind by laser or mechanical drilling of the at least one via 225.

Persons of ordinary skill in the art would appreciate that direct electroplating of the at least one via 225 is not possible since the first and second conducting layers 206, 207 are separated by the dielectric LCP substrate layer 205. In order to allow electroplating, a conductive region or bridge is first coated over the LCP substrate layer 205 within the at least one via 225. In embodiments, the conductive bridge is created by shadow plating or electroless copper plating.

In some embodiments, the at least one via 225 is subjected to electroless copper plating where the base film 220 is immersed in a series of baths that include a catalyst (usually palladium) followed by an alkaline, chelated solution of copper. Copper is thereby chemically bonded to all surfaces that are immersed. This chemically bonded coating is rather thin, but it allows electrical current to flow across the dielectric 205, which enables electroplating. As a result of electroless plating, the at least one via 225 has a coating of copper that is both electrically and mechanically robust.

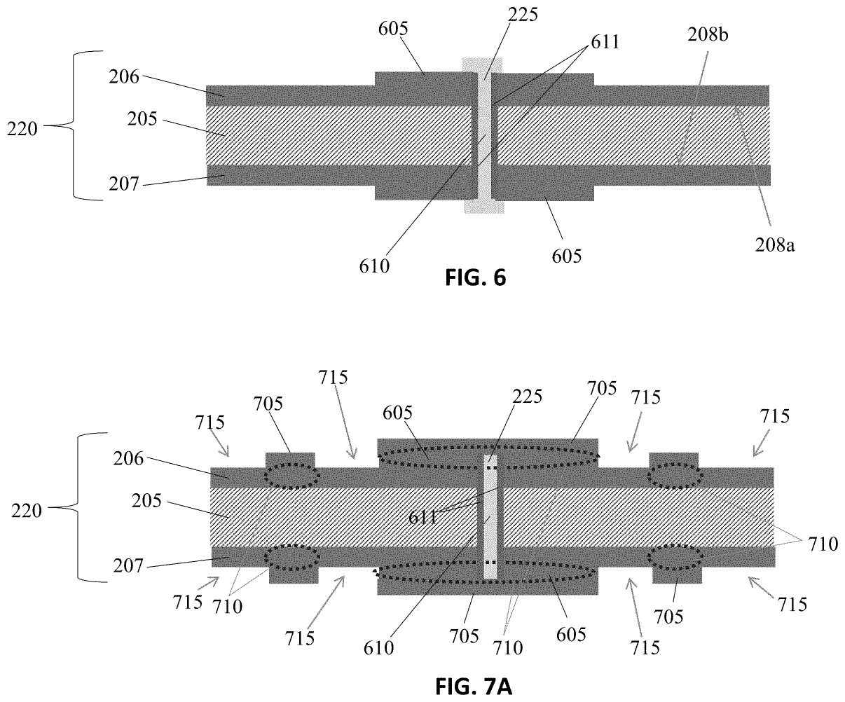

In some embodiments, as shown in FIG. 4, the at least one via 225 is subjected to shadow plating wherein the base film 220 is immersed in a solution with conductive carbon or graphite particles. The carbon or graphite adheres to the entire surface, creating a thin layer 430. A micro-etch is then performed that removes the carbon or graphite from the conducting layers 206, 207, within the at least one via 225, so that only the dielectric LCP areas (within at least one via 225) remain coated with the thin layer or conductive bridge 430 of carbon or graphite.

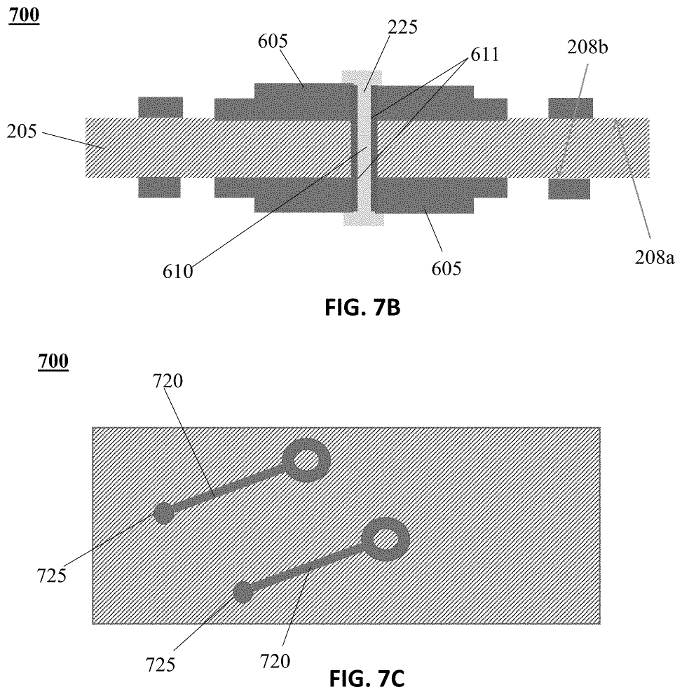

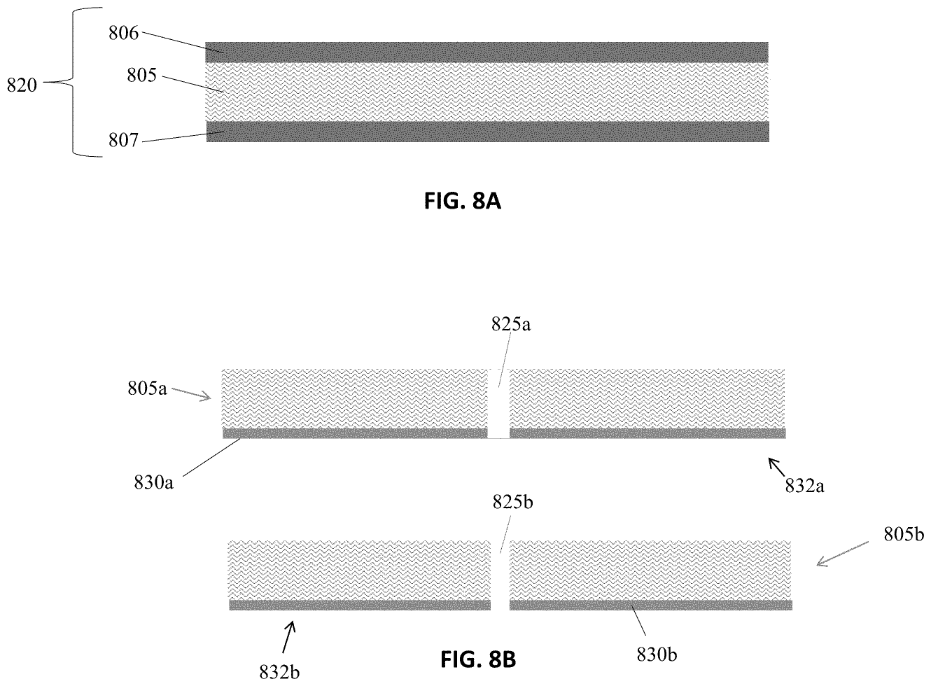

Referring to FIG. 5, once the conductive bridge is created by shadow plating or electroless copper plating, a light sensitive dry film photoresist 505 is applied on the first and second conducting layers 206, 207. The photoresist 505 is exposed to light and developed in the area of the at least one via 225 while the rest of the conducting layers 206, 207 remain covered with the dry film photoresist 505. Thus, the photoresist 505 remains in the regions that need to be protected from a subsequent electroplating process (in FIG. 6) while the region of the at least one via 225 is kept open or devoid of the photoresist 505 for electroplating (in FIG. 6).

Now, referring to FIG. 6, walls of the at least one via 225 are lined or electroplated with a metal or other electrically conductive material 611 and/or the at least one via 225 is filled with the metal or other electrically conductive material 610 such as copper or silver paste. In some embodiments, annular rings 605, corresponding to entry and exit of the at least one via 225, are also electroplated with the metal 610. As known to persons of ordinary skill in the art, an annular ring is an area on a pad that surrounds entry and exit of a through-hole via. In some embodiments, to fill the at least one via 225, metal 610 is grown through electroplating to overflow the filled at least one via 225 and on to the surfaces of the conducting layers 206, 207. The overflowed metal is then etched back to smoothen the surfaces of the first and second conducting layers 206, 207. The photoresist 505 (of FIG. 5) is also stripped. In some embodiments, the at least one via 225 is filled with a solder paste or other conductive material is deposited or printed to fill the at least one via 225.

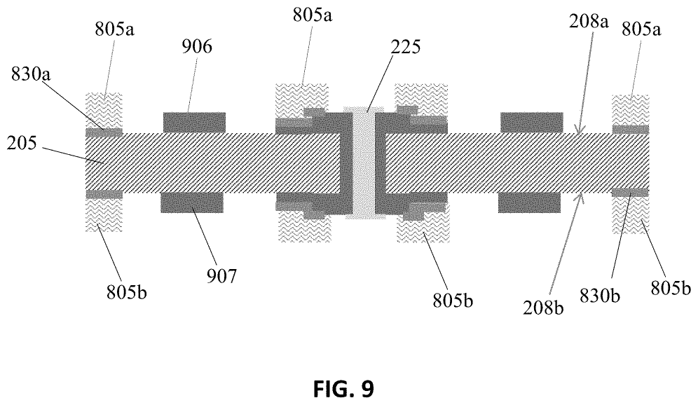

Referring to FIG. 7A, designated areas on the first and second conducting layers 206, 207 of the base film 220 (see FIG. 2) are circuitized or patterned through a process of photolithography. In photolithography, the first and second conducting layers 206, 207 to be patterned are first coated with a light sensitive dry film photoresist 705. To transfer an image to the resist, an optical mask or photomask is used to control which portions of the dry resist sheet are exposed to light and which are not. The photomask is created using commercially available CAD software resulting in a Gerber file defining the mask pattern needed for photomask generation.

Next the photoresist 705 is exposed to light through the patterned photomask thereby transferring the mask pattern. The photoresist 705 is sensitive to exposure to short wavelength light such as ultraviolet light. After exposing the photoresist 705, the resist is developed causing the photoresist 705 to be washed away in some regions and retained in others as defined by the portions of the photoresist 705 exposed to light and those in the shadow of the photomask. After developing the photoresist 705, organic photoresist layer mimics the pattern of the photomask through which it was exposed. The portions 710 that are protected by the photoresist 705 and the portions 715 that are exposed to etching depend on whether a positive or a negative photoresist is employed. Because the photoresist 705 comprises an organic compound, it is relatively insensitive to exposure to acids, especially after hard baking. As shown in FIG. 7A, the dry film photoresist 705 tents the at least one via 225 so as to protect the metal in the annular ring 605, the metal 611 on the walls of the at least one via 225 and the metal 610 filled in the at least one via 225 from being etched away.

The metal, in portions 715, is then etched in acid and thereafter the photoresist 705 is stripped and the mask is also removed. As shown in FIGS. 7B and 7C, the photolithographic process generates desired conductive trace patterns 720 and pads 725 in the first and second conducting layers 206, 207 (FIG. 7A). The metal in the annular ring 605 and the metal 610 in the at least one via 225 (as well as the metal 611 in the walls of the at least one via 225) remains protected (from etching) due to photoresist tenting. Thereafter, automated optical inspection (AOI) of the FCB 700 is carried out to detect defects, if any. Subsequently, the quality checked and approved FCB 700 is baked at a predetermined temperature and for a predetermined period of time to remove any moisture. In some embodiments, the FCB 700 is baked at a temperature of about 180° F. for about 130 minutes.

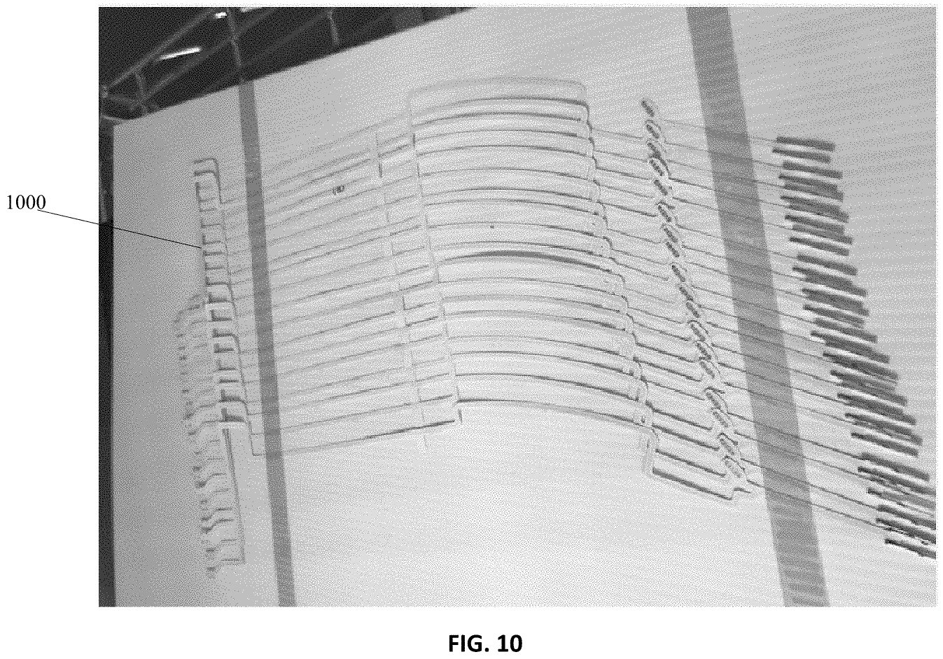

In accordance with aspects of the present specification, the first and second sides 208a, 208b of the FCB 700 are respectively encapsulated by cover layers or films to protect the formed conductive trace patterns 720 and pads 725 against oxidation and mechanical stress or wear. Referring now to FIG. 8A, in some embodiments, in order to fabricate the cover layers a roll or sheet of flexible conductor-clad base film 820 is taken. The base film 820 comprises a LCP substrate layer 805 sandwiched between first and second conducting layers 806, 807. In some embodiments, the flexible conductor-clad base film 820 is similar to the base film 220 of FIG. 2 in terms of the thickness of the LCP substrate layer 805 and that of the first and second conducting layers 806, 807. In some embodiments, the LCP substrate layer 805 has a thickness of 50 micron while each of the first and second conducting layers 806, 807 has a thickness of 18 micron. The first and second conducting layers 806, 807 are stripped from both sides of the LCP substrate layer 805.

In alternate embodiments, a roll or sheet of stand-alone LCP substrate layer 805 (of a thickness of, say, 50 micron) is taken (instead of the conductor-clad base film 820) thereby obviating the need to strip the conducting layers. In one embodiment, the stand-alone LCP substrate layer 805 is a Panasonic R-F705S series LCP of a thickness of 2 mils.

Now, as shown in FIG. 8B, first and second cover layers 805a, 805b are obtained by cutting to size the roll or sheet of LCP substrate layer 805. Thereafter, first and second laminate adhesive layers 830a, 830b are rolled, respectively, on one side 832a, 832b respectively of the corresponding cover layers 805a, and 805b. In some embodiments, each of the adhesive layers 830a, 830b has a predefined thickness. In some embodiments, each of the adhesive layers 830a, 830b has a thickness ranging from 0.5 to 4 mils (that is, approximately 12 to 100 μm). In some embodiments, the adhesive layers 830a, 830b may be applied as a sheet, a spray, a gel, or a paste. While the adhesive layers 830a, 830b are shown as separate layers, in some embodiments, the adhesive layers may be impregnated into the sides 832a, 832b of the corresponding cover layers 805a, and 805b. In embodiments, the layers 830a, 830b comprise bonding adhesives such as, but not limited to, an epoxy, an insulating potting compound, acrylic adhesives, or polyimide adhesives. In embodiments, the adhesive layers 830a, 830b can have good electrical properties similar to the LCP cover layers 805a, 805b. The dielectric constant (Dk) of LCP is less than 3.0, or about 2.9, while the dissipation factor (Df) is less than 0.0025, or about 0.002 at 10 GHz. The adhesive layers 830a, 830b with similar electrical properties enhance the performance of the FCB. In one embodiment, each of the layers 830a, 830b is a Taiflex BT20 epoxy adhesive film of 0.8 mils thickness.

Subsequently, at least one via opening 825a is laser formed through the first cover layer 805a and adhesive layer 830a while at least one via opening 825b is laser formed through the second cover layer 805b and adhesive layer 830b. In the current embodiment, the formation of the vias 825a, 825b corresponds to the entrance and exit sides of the at least one (through-hole) via 225 of the FCB 700 (FIGS. 7B, 7C). However, it should be appreciated that, in various embodiments, the formation of one or more vias in the cover layers is based upon the design of the FCB to be covered or encapsulated.

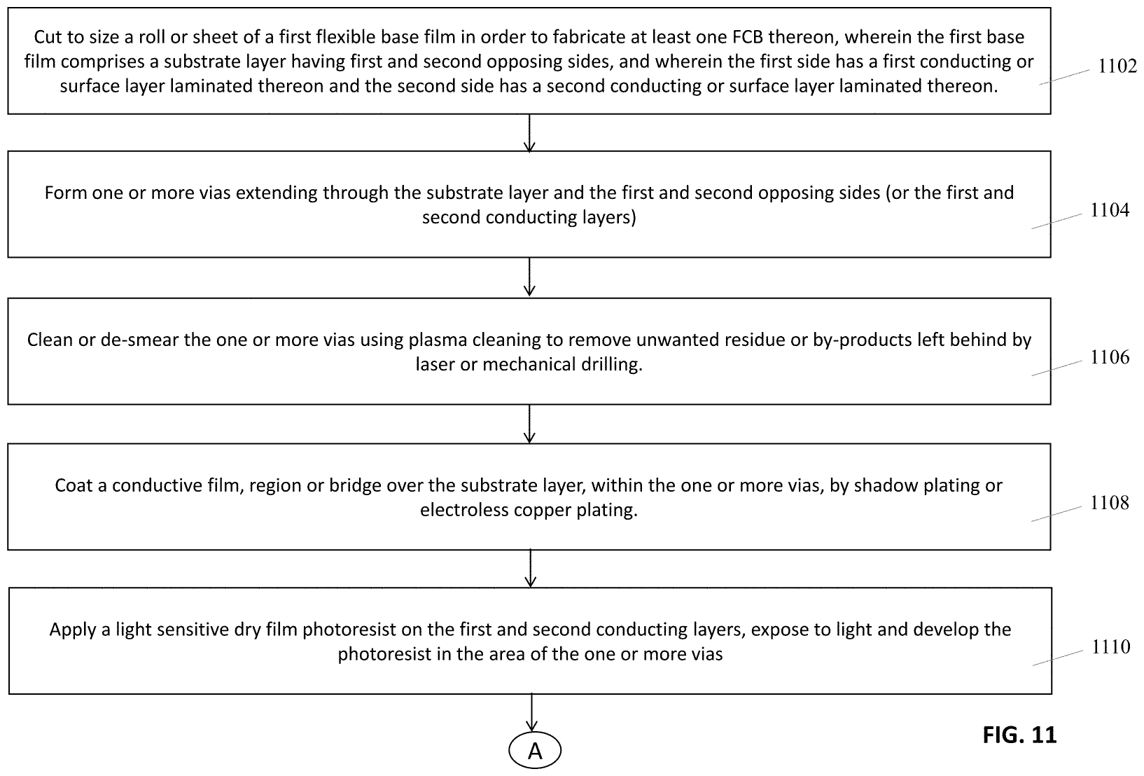

As shown in FIG. 9, the first cover layer 805a with the adhesive layer 830a is aligned over the first side 208a of the FCB 700 of FIG. 7B (using alignment targets positioned on the first side 208a of the FCB 700 and the first cover layer 805a) and tacked in place using heat. Thereafter, the second cover layer 805b with the adhesive layer 830b is aligned over the second side 208b of the FCB 700 of FIG. 7B (using alignment targets positioned on the second side 208b of the FCB 700 and the second cover layer 805b) and tacked in place using heat. In some embodiments, alignment is accomplished by using fiducials or a method of pin alignment is utilized.

Finally, the FCB 700 encapsulated with the first and second cover layers 805a, 805b is vacuum laminated in a hydraulic press. In some embodiments, the lamination is done at a pressure of 250 psi, temperature of about 360° F. and for a duration ranging from 1 hour to 2.5 hours.

In some embodiments, the exposed conducting or metal surfaces, of the FCB 700 encapsulated with the first and second cover layers 805a, 805b, are treated with an ENIG (Electroless Nickel Immersion Gold) surface finishing or plating process. The gold plated over copper, in the ENIG process, is used to prevent the Cu from being oxidized. In alternate embodiments, other surface finishing or plating processes may be applied such as, but not limited to, HASL (Hot Air Solder Leveling), lead free solder, tin, OSP (Organic Solderability Preservative) that involves coating bare copper with a coating that prevents the copper from oxidizing, ENEPIG (Electroless Nickel, Palladium and Gold) and silver. As shown in FIG. 9, the FCB encapsulated with the first and second cover layers 805a, 805b may have certain conducting or metal surfaces 906, 907 exposed to enable an end-user to attach necessary components at the exposed surfaces. For example, the end-user may attach surface mountable components such as, for example, resistors, capacitors, BGA package, or any pin connector through a plated through hole. In embodiments, the exposed conducting or metal surfaces 906, 907 may be pads (circular, square, rectangular) or plated through-holes, such as the via 225, with annular ring.

Thereafter, electrical testing of the FCB 700 encapsulated with the first and second cover layers 805a, 805b is conducted. In some embodiments, the electrical testing is a continuity check for shorts and opens. In some embodiments, a continuity test was conducted using a resistance of up to 10 K ohm, and isolation test was conducted using a resistance of up to 25 M ohm. Voltages used comprises voltages of up to 1 Kv, with typical a voltage of 100 V. In embodiments, where fabrication of a plurality of FCBs is done on a single panel, each of the plurality of FCBs is laser routed for singulation. The FCBs are subjected to final inspection and testing.

Laser routing of the circuits to singulate them carbonizes the LCP material that re-deposits on the cut walls/edges. Also, in cases or designs where conducting metal traces need to be cut-through during singulation, decomposed particles from the cut metal (such as copper, for example) traces re-deposit on the walls or edges. If the walls are not cleaned well, these particles (of carbon and metal) exhibit conductive properties and, during test, result in high resistance values or shores. A method of effectively removing the carbon and metal residues from the walls/edges involves designing and laser cutting a wider window in the critical areas (that need to be laser routed). This wider window allows better access so that a subsequent plasma cleaning step (consisting of plasmas of gases such as, for example, tetrafluoromethane, oxygen or argon) may be performed to effectively clean the carbon/metal residues from the walls/edges.

In accordance with some embodiments, the FCB 700 encapsulated with the first and second cover layers 805a, 805b is subjected to at least one or more of the following tests: a) sonication wash with a base, such as potassium hydroxide (KOH), b) autowash, c) autoclave sterilization and d) voltage leakage test. In some embodiments, harnesses are assembled into the FCB 700 for subjecting to disinfecting and sterilization wash cycles. In some embodiments, the disinfecting and sterilization is as follows: a) disinfecting for 10 to 80 minutes, preferably about 40 minutes, using a base solution, such as potassium hydroxide having pH of 11, and/or b) sterilization using steam for 5 to 30 minutes, preferably for 18 minutes (137 degrees Celsius steam autoclave). Thereafter, the rear housing is rotated which rolls (that is, moves) a service loop radius is moved (around 0.25 inch radius) in between each disinfecting and sterilization cycle. The test is continued until failure. During testing, the electrical harness surpassed the mechanicals and the cleaning cycles were exceeded.

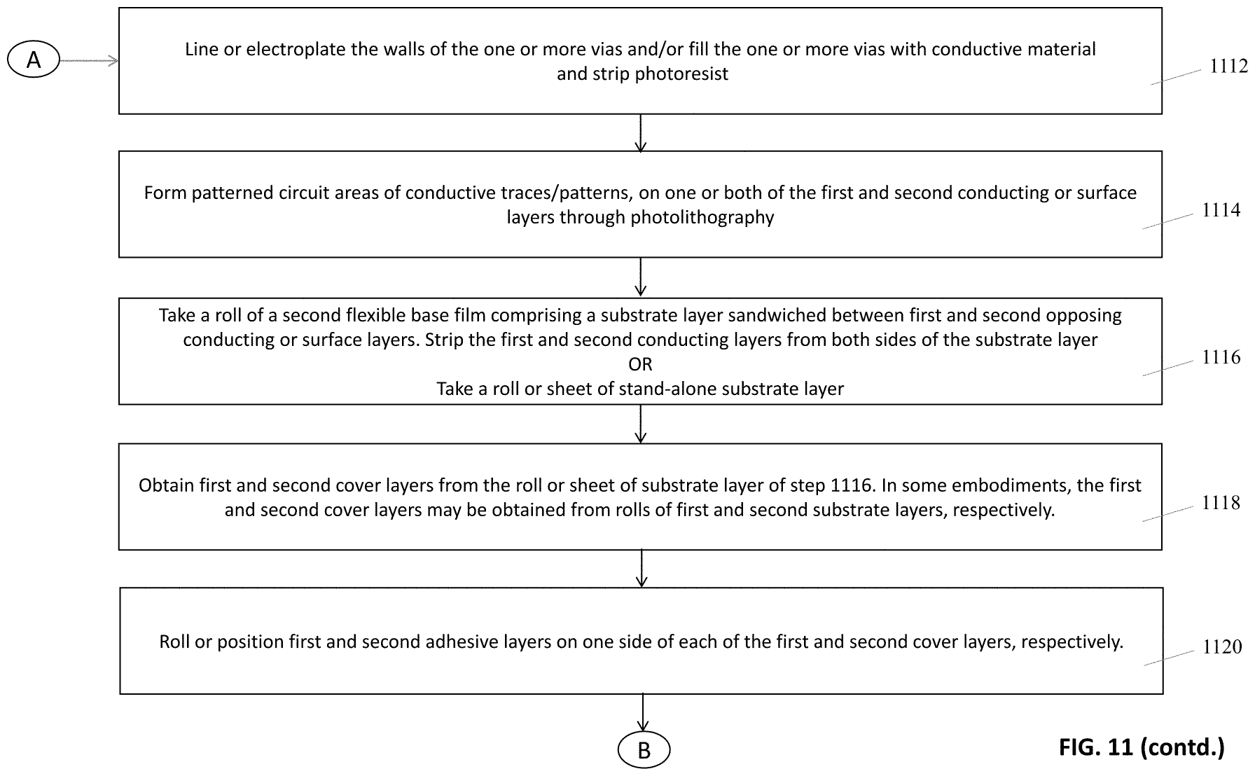

FIG. 10 shows a finished or final FCB product 1000 for shipping to an end-user for further processing. The FCB product 1000 is flex cable with two contact pins solder on one end.

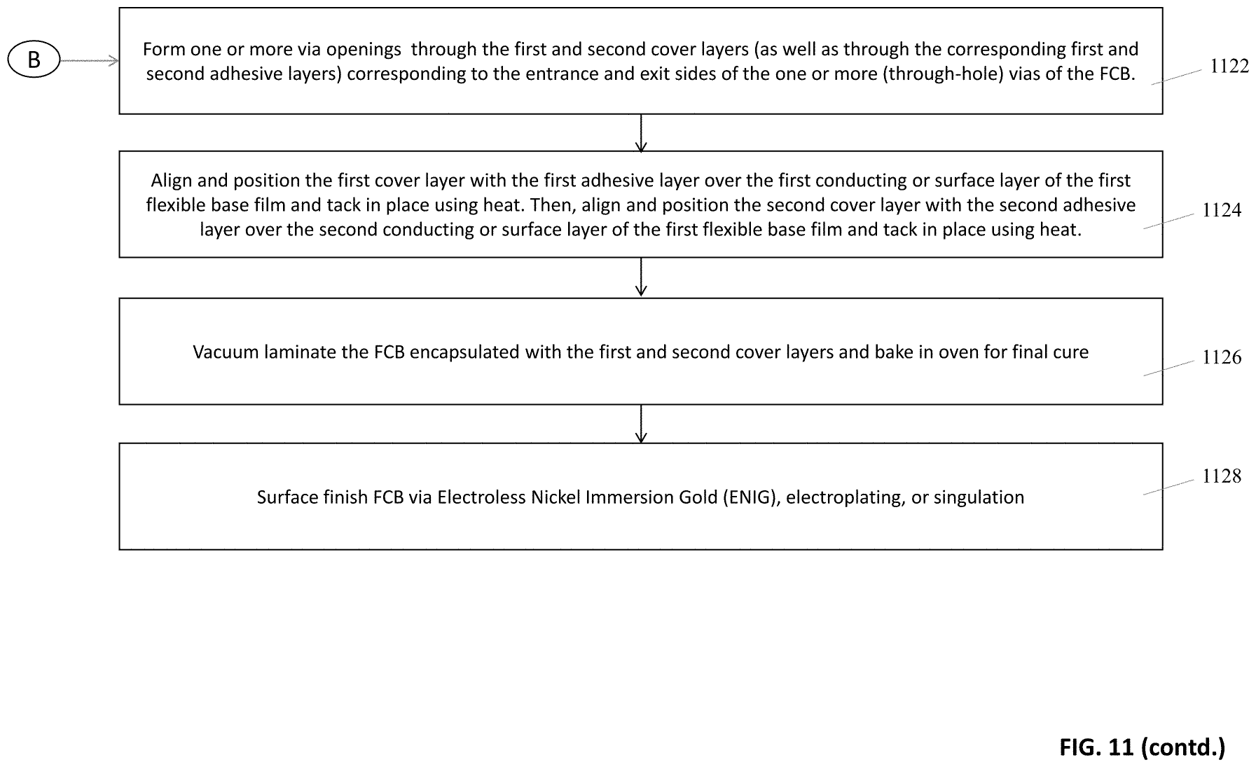

FIG. 11 is a flowchart of a plurality of exemplary steps of a method of manufacturing of the FCB of the present specification. At step 1102, a first flexible base film is received in the form of a roll or sheet and cut to size in order to fabricate at least one FCB thereon. In some embodiments, the first flexible base film comprises a substrate layer having first and second opposing sides. The first side has a first conducting or surface layer laminated thereon and the second side has a second conducting or surface layer laminated thereon. In some embodiments, the substrate layer (of the first base film) is of a first liquid crystal polymer.

At step 1104, one or more openings, holes or vias are formed in the first base film by an ultraviolet (UV) based laser, a carbon dioxide based laser, or by any other known methods, such as, but not limited to, mechanical drilling, depth-controlled laser drilling or punching. In some embodiments, the one or more vias extend through the substrate layer and the first and second opposing sides. In some embodiments, the one or more vias extend through the substrate layer and the first and second conducting or surface layers. In various embodiments, one or more through-hole, blind and/or buried vias may be formed depending upon the desired design and surface mount of the FCB.

At step 1106, the one or more openings, holes or vias are cleaned or de-smeared using plasma cleaning to remove unwanted residue or by-products left behind by laser or mechanical drilling. At step 1108, a conductive film, region or bridge is coated over the substrate layer, within the one or more vias, by shadow plating or electroless copper plating. Thereafter, at step 1110, a light sensitive dry film photoresist is applied on the first and second conducting or surface layers and the photoresist is exposed to light and developed in the area of the one or more vias while the rest of the first and second conducting or surface layers remain covered with the dry film photoresist.

Now, at step 1112, walls of each of the one of more vias are lined or electroplated with a metal or other electrically conductive material and/or each of the one or more vias are filled with the metal or other electrically conductive material such as copper or silver paste. In some embodiments, annular rings, corresponding to entry and exit of each of the one or more vias, are also electroplated with the metal or other electrically conductive material. In some embodiments, to fill each of the one of more vias, metal is grown through electroplating to overflow each of the filled one of more vias and on to the surfaces of the first and second conducting or surface layers. The overflowed metal is then etched back to smoothen the surfaces of the first and second conducting layers. The photoresist is also stripped. In some embodiments, each of the one of more vias is filled with a solder paste or other conductive material is deposited or printed to fill each of the one of more vias.

Next, at step 1114, designated areas on one or both of the first and second conducting or surface layers are circuitized or patterned through photolithography to form patterned circuit areas of conductive traces/patterns. Thus, as a result of the process of photolithography, a plurality of conductive traces are formed or positioned on at least one of the first and second opposing sides of the LCP substrate layer or on at least one of the first and second conducting or surface layers of the base film. Thereafter, automated optical inspection (AOI) of the FCB is carried out to detect defects, if any. Subsequently, the quality checked and approved FCB is baked at a predetermined temperature and for a predetermined period of time to remove any moisture.

Now, at step 1116, a roll or sheet of a second flexible base film is taken. In some embodiments, the second base film comprises a substrate layer sandwiched between first and second opposing conducting or surface layers. The first and second conducting layers are stripped from both sides of the substrate layer. In some embodiments, a roll or sheet of stand-alone substrate layer is taken thereby obviating the need to strip the conducting layers. Then, at step 1118, the roll or sheet of the substrate layer (from step 1116) is cut to size to obtain first and second cover layers. In some embodiments, the substrate layer (of the first base film) is of a second liquid crystal polymer. In alternate embodiments, the first cover layer is obtained from a roll or sheet of substrate layer comprising a second liquid crystal polymer while the second cover layer is obtained from another roll or sheet of substrate layer comprising a third liquid crystal polymer. In other words, the first cover layer is obtained from a roll or sheet of second substrate layer while the second cover layer is obtained from another roll or sheet of third substrate layer.

Thereafter, at step 1120, in some embodiments, first and second laminate adhesive layers are rolled or positioned, respectively, on one side of each of the first and second cover layers. In embodiments, the adhesive layers may be applied as a sheet, a spray, a gel, or a paste. Subsequently, at step 1122, one or more via openings are laser formed through the first and second cover layers (as well as through the corresponding first and second adhesive layers) corresponding to the entrance and exit sides of the one or more (through-hole) vias of the FCB. Then, at step 1124, the first cover layer with the first adhesive layer is aligned and positioned over the first conducting or surface layer of the first flexible base film and tacked in place using heat. Subsequently, the second cover layer with the second adhesive layer is aligned and positioned over the second conducting or surface layer of the first flexible base film and tacked in place using heat.

At step 1126, the FCB encapsulated with the first and second cover layers is vacuum laminated in a hydraulic press and then baked in an oven for a final cure. In some embodiments, at step 1128, certain exposed conducting or metal surfaces of the FCB, encapsulated with the first and second cover layers, are treated with a surface finishing or plating process, such as ENIG, or undergo singulation. Thereafter, electrical testing of the FCB encapsulated with the first and second cover layers is conducted. In accordance with some embodiments, the FCB encapsulated with the first and second cover layers is subjected to at least one or more of the following tests: a) sonication wash with a base, such as potassium hydroxide (KOH), b) autowash, c) autoclave sterilization and d) voltage leakage test.

The above examples are merely illustrative of the many applications of the system and method of present specification. Although only a few embodiments of the present specification have been described herein, it should be understood that the present specification might be embodied in many other specific forms without departing from the spirit or scope of the specification. Therefore, the present examples and embodiments are to be considered as illustrative and not restrictive, and the specification may be modified within the scope of the appended claims.

1. A circuit board comprising:
a substrate comprising a first liquid crystal polymer and two opposing sides, wherein the first of the two opposing sides defines a first surface layer and wherein the second of the two opposing sides defines a second surface layer;
one or more vias extending through the substrate and two opposing sides, wherein each of the one or more vias comprises conductive material;
a plurality of conductive traces positioned on at least one of the two opposing sides;
a first adhesive positioned on the first surface layer;
a second adhesive positioned on the second surface layer;
a first cover layer positioned over the first adhesive on the first surface layer, wherein the first cover layer comprises a second liquid crystal polymer; and
a second cover layer positioned over the second adhesive on the second surface layer, wherein the second cover layer comprises a third liquid crystal polymer.

2. The circuit board of claim 1 wherein the first liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

3. The circuit board of claim 1 wherein the second liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

4. The circuit board of claim 1 wherein the third liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

5. The circuit board of claim 1 wherein the first liquid crystal polymer, second liquid crystal polymer, and third liquid crystal polymer are a same liquid crystal polymer.

6. The circuit board of claim 1 wherein the first liquid crystal polymer has a thickness in a range of 25 to 75 microns.

7. The circuit board of claim 1 wherein each of the first liquid crystal polymer or second liquid crystal polymer has a thickness in a range of 25 to 75 microns.

8. The circuit board of claim 1 wherein the adhesive covers all of the first surface layer.

9. The circuit board of claim 8 wherein the adhesive covers all of the second surface layer.

10. The circuit board of claim 1 wherein the first liquid crystal polymer has a thickness that is less than a thickness of the second liquid crystal polymer and less than a thickness of the third liquid crystal polymer and wherein the thickness of the second liquid crystal polymer is equal to the thickness of the third liquid crystal polymer.

11. The circuit board of claim 1 wherein the first liquid crystal polymer has a thickness that is more than a thickness of the second liquid crystal polymer and more than a thickness of the third liquid crystal polymer and wherein the thickness of the second liquid crystal polymer is equal to the thickness of the third liquid crystal polymer.

12. The circuit board of claim 1 wherein the first liquid crystal polymer has a thickness that is equal to a thickness of the second liquid crystal polymer and equal to a thickness of the third liquid crystal polymer and wherein the thickness of the second liquid crystal polymer is equal to the thickness of the third liquid crystal polymer

13. The circuit board of claim 1, wherein, in each of the one or more vias, the conductive material is configured to interconnect one of the plurality of conductive traces on the first surface layer with another one of the plurality of conductive traces on the second surface layer.

14. A circuit board comprising:
a liquid crystal polymer substrate defined by a thickness of 25 to 75 microns and including two opposing sides, wherein the first of the two opposing sides defines a first surface layer and wherein the second of the two opposing sides defines a second surface layer;
one or more vias extending through the substrate and two opposing sides, wherein each of the one or more vias comprises at least one of conductive material or material plated to one or more walls of each of the one or more vias;
a plurality of conductive traces positioned on at least one of the two opposing sides, wherein each of the one or more vias is configured to interconnect one of the plurality of conductive traces on the first surface layer with another one of the plurality of conductive traces on the second surface layer;
a first adhesive positioned on the first surface layer, wherein the adhesive covers all of the first surface layer;
a second adhesive positioned on the second surface layer, wherein the adhesive covers all of the second surface layer;
a first cover layer positioned over the first adhesive on the first surface layer, wherein the first cover layer comprises a second liquid crystal polymer; and
a second cover layer positioned over the second adhesive on the second surface layer, wherein the second cover layer comprises a third liquid crystal polymer.

15. The circuit board of claim 14 wherein each of the first liquid crystal polymer, the second liquid crystal polymer, and the third liquid crystal polymer is at least one of a partially crystalline aromatic polyesters, a polyester comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, a polyester comprising monomer units derived from 4-hydroxybenzoic acid, terephthalic acid and 4,4′-biphenol, or a polyester comprising one or more aromatic dicarboxylic acids and alicyclic dicarboxylic acids, one or more aromatic diols, alicyclic diols and aliphatic diols, one or more aromatic hydroxy-carboxylic acids, one or more aromatic thiocarboxylic acids, one or more aromatic dithiols or aromatic dithiophenols, or one or more aromatic hydroxy hydroxylamines or aromatic diamines.

16. The circuit board of claim 15 wherein the first liquid crystal polymer, second liquid crystal polymer, and third liquid crystal polymer are a same liquid crystal polymer.

17. The circuit board of claim 14 wherein the first liquid crystal polymer has a thickness that is less than a thickness of the second liquid crystal polymer and less than a thickness of the third liquid crystal polymer and wherein the thickness of the second liquid crystal polymer is equal to the thickness of the third liquid crystal polymer.

18. The circuit board of claim 14 wherein the first liquid crystal polymer has a thickness that is less than a thickness of the second liquid crystal polymer and less than a thickness of the third liquid crystal polymer.

19. The circuit board of claim 1 wherein the first liquid crystal polymer has a thickness that is equal to a thickness of the second liquid crystal polymer and equal to a thickness of the third liquid crystal polymer.

20. The circuit board of claim 14 wherein the first liquid crystal polymer has a thickness that is more than a thickness of the second liquid crystal polymer and more than a thickness of the third liquid crystal polymer and wherein the thickness of the second liquid crystal polymer is equal to the thickness of the third liquid crystal polymer.
